(19) United States
(12) Patent Application Publication
(10) Pub. No.: US 2021/0054170 A1
(43) Pub. Date: Feb. 25, 2021

(54) POLYMER COMPOSITION FOR APPLICATIONS COMPRISING A LAYER ELEMENT

(71) Applicant: BOREALIS AG, Vienna (AT)

(72) Inventors: Stefan Hellstrom, Stenungsund (SE); Mattias Bergqvist, Goteborg (SE)

(21) Appl. No.: 16/965,918

(22) PCT Filed: Feb. 12, 2019
(86) PCT No.: PCT/EP2019/053419

§ 371 Date: Jul. 29, 2020

(30) Foreign Application Priority Data
Feb. 15, 2018 (EP) 18156880.9

(51) Int. Cl. C08K 5/3435; C08K 5/5425; H01L 31/048; H01L 31/18

(52) U.S. Cl. CPC C08K 5/3435; H01L 31/18; H01L 31/0481; C08K 5/5425

(57) ABSTRACT

The present invention relates to a polymer composition, to an article comprising the polymer composition, preferably to an article comprising at least one layer element (LE) comprising the polymer composition, and to a process for producing said article.

The present invention relates to a polymer composition, to a layer element (LE), to an article comprising the polymer composition, preferably to an article comprising a layer element (LE), to a use of polymer composition, preferably (LE), for producing an article, and to a process for producing an article.

### BACKGROUND ART

As an example of articles comprising a layer element, for instance articles which are monolayer elements, like monolayer films; articles which are multilayer elements, like multilayer films; articles which comprise two or more layer elements for photovoltaic devices; articles which comprise two or more layer elements for construction applications, like elements in buildings, for instance architectural elements, such as exterior/interior elements, like facades outside the building, window elements, door elements or indoor wall elements; for elements in bridges; for elements in vehicles, such as windows in cars, trains, airplanes or ships; for elements in production equipments, like safety windows in machines; for elements in household devices; for projection applications, like head-up displays, or for elements in furniture etc.

For instance photovoltaic (PV) modules, also known as solar cell modules, produce electricity from light and are used in various kinds of applications, i.a. in outdoor applications, as well known in the field. The type of the photovoltaic module can vary. The modules have typically a multilayer structure, i.e. several different layer elements which have different functions. The layer elements of the photovoltaic module can vary with respect to layer materials and layer structure. The final photovoltaic module can be rigid or flexible.

The above exemplified layer elements can be monolayer or multilayer elements. Typically the layer elements of PV module are assembled in order of their functionality and then laminated together to form the integrated PV module. Moreover, there may be adhesive layer(s) between the layers of an element or between the different layer elements.

The photovoltaic (PV) module can for example contain, in a given order, a protective front layer element which can be flexible or rigid (such as a glass layer element), front encapsulation layer element, a photovoltaic element, rear encapsulation layer element, a protective back layer element, which is also called a backsheet layer element and which can be rigid or flexible; and optionally e.g. an aluminium frame.

Accordingly, part or all of the layer elements of a PV module, e.g. the front and rear encapsulation layer elements, and often the backsheet layer, are typically of a polymeric material, like ethylene vinyl acetate (EVA) based material.

Sometime the adhesion between two layer elements after lamination may not be sufficient for the demands needed for the desired end application, due to properties of one or both of the layer element(s).

There is a continuous need to provide further layer element compositions to provide advanced solutions for different end use applications.

### FIGURES

FIG. 1 illustrates a photovoltaic (PV) module as one preferable article of the layer element (LE) of the invention, wherein the PV module comprises the following layer elements (separated in FIG. 1), in given order: a protective front layer element (1), a front encapsulation layer element (2), a photovoltaic element (3), a rear encapsulation layer element (4) and a protective back layer element (5) of a photovoltaic module, wherein at least the rear encapsulation layer element (4) comprises the polymer composition of the invention, preferably wherein at least one layer element, preferably one or both, preferably both, of the front encapsulation layer element (2) and/or rear encapsulation layer element (4) comprises, preferably consists of the layer element (LE) of the invention.

FIG. 2 illustrates a laminated glass element for instance for safety, insulation or thermal applications, which all have a well-known meaning in the art. In FIG. 2 the laminated glass element comprises a first layer element (1), a layer element (LE) of the invention comprising the polymer composition of the invention and a second layer element (2).

### THE DESCRIPTION OF THE INVENTION

Accordingly, the present invention is directed to a polymer composition comprising
a polymer (P);
silane group(s) containing units (b); and
a hindered amine compound (HALS) comprising a unit of formula (A0):

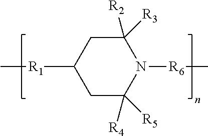

wherein

R₁ is a substituted or unsubstituted (C1-C20)hydrocarbylene group optionally interrupted with one or more heteroatom(s) selected from —O—, —N═ or —NR—; or a heteroatom selected from —O—, —N═ or —NR—;

R₂, R₃, R₄ and R₅ are each independently selected from a substituted or unsubstituted (C1-C20)hydrocarbyl group optionally interrupted with one or more heteroatom(s) selected from —O—, —N═ or —NR—;

R₆ is selected from substituted or unsubstituted (C1-C20)hydrocarbylene group optionally interrupted with one or more heteroatom(s) selected from —O—, —N═ or —NR—; provided that R₆ is attached to the ring atom of unit of formula (A0) via atom other than oxygen, —O—;

wherein the number of optional substituent(s) of each of R₁ to R₆ is independently selected from 1, 2 or 3; and the optional substituent(s) of each R₁ to R₆ are independently selected (C1-C20)hydrocarbyl group which can optionally be interrupted with one or more heteroatom(s) selected from —O—, —N═ or —NR— and which can optionally be substituted with (C1-C20)hydrocarbyl group optionally interrupted with one or more heteroatom(s) selected from —O—, —N═ or —NR—; or ═O group; or —N(R)₂;

R is independently selected from H or linear (C1-C8)alkyl group; and n is 1 to 20.

The polymer composition, as defined above, below or in claims, is also referred herein as “polymer composition of the invention” or as the “composition of the invention” or “polymer composition”.

The silane group(s) containing units (b), as defined above, below or in claims, is also referred herein as silane group(s) containing units.

The hindered amine compound (HALS) comprising a unit of formula (A0), as defined above, below or in claims, means herein that the HALS must contain said unit of formula (A0) and wherein the unit of formula (A0) is terminated with end groups to form the final hindered amine compound (HALS) (A) which is referred herein also shortly as “HALS of formula (A)”, “HALS compound (A)”, “HALS (A)” or “HALS”.

In the definitions of the substituents of unit of formula (A0), and as said above in the HALS of formula (A): The term “hydrocarbylene group” means a divalent group formed by removing two hydrogen atoms from a hydrocarbon, the free valencies of which are not engaged in a double bond, e.g. 1,3-phenylene, —CH2CH2CH2-propane-1,3-diyl, —CH2-methylene (according to IUPAC nomenclature). Moreover, the term “hydrocarbyl group” means a univalent group formed by removing a hydrogen atom from a hydrocarbon, e.g. ethyl, phenyl (according to IUPAC nomenclature).

It has been surprisingly found that the present polymer composition with the specific HALS compound (A) can provide a layer element (LE) with improved adhesion after lamination on a substrate, and, preferably, in addition to improved adhesion directly after lamination also improved adhesion after damp heat conditions.

Without binding to any theory it is believed that the HALS compound (A) has minor or even insignificant crosslinking activity of the polymer composition containing silane group(s) containing polymer composition.

Furthermore, the polymer composition of the invention enables, if desired, to produce peroxide-free layer elements.

Moreover, the polymer composition is highly suitable for articles, like for photovoltaic (PV) modules; for construction applications, elements in vehicles, elements in production equipments, elements in projection applications, elements in furniture etc.

In a further aspect of the invention, also the use of the polymer composition as defined above or below or in claims is provided for producing a layer element (LE) comprising one or more layer(s), wherein at least one layer comprises the polymer composition of the invention.

In a further aspect, the invention further provides a layer element (LE) of one or more layers, wherein at least one layer comprises the polymer composition as defined above, below or in claims. The layer element (LE) of the invention is referred herein also as layer element (LE).

In a further aspect, the invention further provides an article comprising the polymer composition. Preferably, the invention further provides an article comprising the layer element (LE) of the invention.

In a further aspect, the invention further provides the use of the polymer composition as defined above or below or in claims for producing an article, preferably a photovoltaic (PV) module, comprising a layer element (LE) comprising one or more layer(s), preferably one layer, which comprises the polymer composition as defined above or below or in claims.

The article is preferably an assembly comprising two or more layer elements, wherein at least one layer element is the layer element (LE).

The article is more preferably a photovoltaic (PV) module comprising a photovoltaic element and one or more further layer elements, wherein at least one layer element, preferably one layer element, is the layer element (LE), as defined above or below or in claims.

The invention further provides a photovoltaic (PV) module comprising, in the given order, a protective front layer element, a front encapsulation layer element, a photovoltaic element, a rear encapsulation layer element and a protective back layer element, wherein, preferably, at least one layer element, preferably one or both, preferably both, of the front encapsulation layer element and/or the rear encapsulation layer element comprises, preferably consists of, the layer element (LE) of the invention, as defined above, below or in claims.

The invention further provides a process for producing an article comprising two or more layer elements, wherein at least one layer element is the layer element (LE) of the invention, comprising the steps of
assembling the layer element (LE) and one or more further layer elements to an assembly;
laminating the layer elements of the assembly in elevated temperature to adhere the elements together; and
recovering the obtained article; as defined above or below or in claims.

The polymer composition, the polymer (P), HALS, the layer element (LE), the article, preferably PV module, and process of the invention for producing the article; together with further details, preferred embodiments, ranges and properties thereof, are described below and in claims, which preferred embodiments, ranges and properties can be in any combination and combined in any order.

The Polymer Composition

Preferably, the HALS (A) is a compound of formula (A1), wherein

wherein

R₁ is a substituted or unsubstituted (C1-C20)hydrocarbylene group optionally interrupted with 1, 2, or 3 heteroatom(s) selected from —O—, —N═ or —NR—; or a heteroatom selected from —O—, —N═ or —NR—;

R₂, R₃, R₄ and R₅ are each independently selected from a substituted or unsubstituted (C1-C20)hydrocarbyl group optionally interrupted with 1, 2, or 3 heteroatom(s) selected from —O—, —N═ or —NR—;

R₆ is selected from substituted or unsubstituted (C1-C20)hydrocarbylene group optionally interrupted with 1, 2, or 3 heteroatom(s) selected from —O—, —N═ or —NR—; provided that R₆ is attached to the ring atom of unit of formula (A1) via atom other than oxygen, —O—;

wherein the number of optional substituent(s) of each of R₁ to R₆ is independently selected from 1, 2 or 3; and the optional substituent(s) of each R₁ to R₆ are independently selected (C1-C20)hydrocarbyl group which can optionally be interrupted with 1, 2, or 3 heteroatom(s) selected from —O—, —N═ or —NR— and which can optionally be substituted with (C1-C20)hydrocarbyl group optionally interrupted with 1, 2, or 3 heteroatom(s) selected from —O—, —N═ or —NR—; or ═O group; or —N(R)₂;

R is independently selected from H or linear (C1-C8)alkyl group; and

n is 2 to 20.

Preferably, the HALS (A) is a compound of formula (A2), wherein

R₁ is selected from a substituted or unsubstituted, saturated or unsaturated, straight or branched chain (C1-C20)alkylene group optionally interrupted with 1, 2, or 3 heteroatom(s) selected from —O—, —N═ or —NR—; a substituted or unsubstituted, unsaturated or partially saturated cyclic (C5-C8)alkylene group optionally having 1, 2 or 3 ring heteroatoms selected from —O—, —N═ or —NR—; a substituted or unsubstituted cyclic (C5-C8)arylene group optionally having 1, 2 or 3 ring heteroatoms selected from —O—, —N═ or —NR—; a substituted or unsubstituted (C1-C20)alkylene-cyclic (C5-C8)alkylene group which is optionally interrupted with —O—, —N═ or —NR—; a substituted or unsubstituted (C1-C20)alkylene-(C5-C8)arylene group which is optionally interrupted with —O—, —N═ or —NR—; a substituted or unsubstituted cyclic (C5-C8)alkylene-(C1-C20)alkylene group which is optionally interrupted with —O—, —N═ or —NR—; a substituted or unsubstituted (C5-C8)arylene-(C1-C20)alkylene group which is optionally interrupted with —O—, —N═ or —NR—; or a heteroatom selected from —O— or —NR—;

R₂, R₃, R₄ and R₅ are each independently selected from a substituted or unsubstituted, saturated or unsaturated, straight or branched chain (C1-C20)hydrocarbyl group optionally interrupted with 1, 2 or 3 heteroatom(s) selected from —O—, —N═ or —NR—;

R₆ is selected from a substituted or unsubstituted, saturated or unsaturated, straight or branched chain (C1-C20)alkylene group optionally interrupted with 1, 2, or 3 heteroatom(s) selected from —O—, —N═ or —NR—; a substituted or unsubstituted, unsaturated or partially saturated cyclic (C5-C8)alkylene group optionally having 1, 2 or 3 ring heteroatoms selected from —O—, —N═ or —NR—; a substituted or unsubstituted cyclic (C5-C8)arylene group optionally having 1, 2 or 3 ring heteroatoms selected from —O—, —N═ or —NR—; a substituted or unsubstituted (C1-C20)alkylene-cyclic (C5-C8)alkylene group which is optionally interrupted with —O—, —N═ or —NR—; a substituted or unsubstituted (C1-C20)alkylene-(C5-C8)arylene group which is optionally interrupted with —O—, —N═ or —NR—; a substituted or unsubstituted cyclic (C5-C8)alkylene-(C1-C20)alkylene group which is optionally interrupted with —O—, —N═ or —NR—; a substituted or unsubstituted cyclic (C5-C8)arylene-(C1-C20)alkylene group which is optionally interrupted with —O—, —N═ or —NR—;

and

wherein the number of optional substituent(s) of each of R₁ to R₆ is independently selected from 1, 2 or 3; and the optional substituent(s) of each R₁ to R₆ are independently selected from saturated or unsaturated, straight or branched chain (C1-C20)hydrocarbyl group optionally interrupted with 1, 2 or 3 heteroatom(s) selected from —O—, —N═ or —NR—; a substituted or unsubstituted, unsaturated or partially saturated cyclic (C5-C8)hydrocarbyl group optionally having 1, 2 or 3 ring heteroatoms selected from —O—, —N═ or —NR—; a substituted or unsubstituted (C5-C8)aryl group optionally having 1, 2 or 3 ring heteroatoms selected from —O—, —N═ or —NR—; or ═O group; or —N(R)₂;

R is independently selected from H or linear (C1-C8)alkyl group; and

n is 2 to 20.

In one preferable embodiment the hindered amine compound (HALS) of formula (A) has pH of 9 or less, preferably of 3 to 8.5, preferably of 4 to 8 preferably 5 to 8, more preferably 5.5 to 7.5.

In one preferable embodiment the hindered amine compound (HALS) of formula (A) has a molecular weight of 300 to 6000, preferably 550-5700, preferably 2000-5000, preferably 2700 to 4500. The molecular weight of the hindered amine compound (HALS) is usually disclosed in the technical data sheet of commercially available HALS compounds or can be measured using GPC.

In one preferable embodiment the hindered amine compound (HALS) of formula (A) has Tm of 180° C. or less, preferably 15 to 150° C., preferably 20 to 100° C., preferably 30 to 90° C., preferably 40 to 80° C., most preferably 50 to 60° C.

Preferably, the HALS is a compound of formula (A3), wherein

R₁ is selected from a substituted or unsubstituted, saturated or unsaturated, straight or branched chain (C1-C20)alkylene group optionally interrupted with 1, 2, or 3 heteroatom(s) selected from —O—, —N═ or —NR—; a substituted or unsubstituted, unsaturated or partially saturated cyclic (C5-C8)alkylene group optionally having 1, 2 or 3 ring heteroatoms selected from —O—, —N═ or —NR—; a substituted or unsubstituted cyclic (C5-C8)arylene group optionally having 1, 2 or 3 ring heteroatoms selected from —O—, —N═ or —NR—; a substituted or unsubstituted (C1-C20)alkylene-cyclic (C5-C8)alkylene group which is optionally interrupted with —O—, —N═ or —NR—; a substituted or unsubstituted (C1-C20)alkylene-(C5-C8)arylene group which is optionally interrupted with —O—, —N═ or —NR—; a substituted or unsubstituted cyclic (C5-C8)alkylene-(C1-C20)alkylene group which is optionally interrupted with —O—, —N═ or —NR—; a substituted or unsubstituted (C5-C8)arylene-(C1-C20)alkylene group which is optionally interrupted with —O—, —N═ or —NR—; or a heteroatom selected from —O— or —NR—;

R₂, R₃, R₄ and R₅ are each independently selected from a substituted or unsubstituted, saturated or unsaturated, straight or branched chain (C1-C20)hydrocarbyl group optionally interrupted with 1, 2 or 3 heteroatom(s) selected from —O—, —N═ or —NR—;

R₆ is selected from a substituted or unsubstituted, saturated or unsaturated, straight or branched chain (C1-C20)alkylene group optionally interrupted with 1, 2, or 3 heteroatom(s) selected from —O—, —N═ or —NR—; a substituted or unsubstituted, unsaturated or partially saturated cyclic (C5-C8)alkylene group optionally having 1, 2 or 3 ring heteroatoms selected from —O—, —N═ or —NR—; a substituted or unsubstituted cyclic (C5-C8)arylene group optionally having 1, 2 or 3 ring heteroatoms selected from —O—, —N═ or —NR—; a substituted or unsubstituted (C1-C20)alkylene-cyclic (C5-C8)alkylene group which is optionally interrupted with —O—, —N═ or —NR—; a substituted or unsubstituted (C1-C20)alkylene-(C5-C8)arylene group which is optionally interrupted with —O—, —N═ or —NR—; a substituted or unsubstituted cyclic (C5-C8)alkylene-(C1-C20)alkylene group which is optionally interrupted with —O—, —N═ or —NR—; a substituted or unsubstituted (C5-C8)arylene-(C1-C20)alkylene group which is optionally interrupted with —O—, —N═ or —NR—;

and

wherein the number of optional substituent(s) of each of R₁ to R₆ is independently selected from 1, 2 or 3; and the optional substituent(s) of each R₁ to R₆ are independently selected from saturated or unsaturated, straight or branched chain (C1-C20)hydrocarbyl group optionally interrupted with 1, 2 or 3 heteroatom(s) selected from —O—, —N═ or —NR—; a substituted or unsubstituted, unsaturated or partially saturated cyclic (C5-C8)hydrocarbyl group optionally having 1, 2 or 3 ring heteroatoms selected from —O—, —N═ or —NR—; a substituted or unsubstituted (C5-C8)aryl group optionally having 1, 2 or 3 ring heteroatoms selected from —O—, —N═ or —NR—; or ═O group; or —N(R)₂;

R is independently selected from H or linear (C1-C8)alkyl group; and

n is 2 to 20.

Preferably, the HALS is a compound of formula (A4), wherein

R₁ is selected from a substituted or unsubstituted, saturated or unsaturated, straight or branched chain (C1-C8)alkylene group optionally interrupted with 1, 2, or 3 heteroatom(s) selected from —O—, —N═ or —NR—; a substituted or unsubstituted, unsaturated or partially saturated cyclic (C5-C6)alkylene group optionally having 1, 2 or 3 ring heteroatoms selected from —N═ or —NR—; a substituted or unsubstituted cyclic (C5-C6)arylene group optionally having 1, 2 or 3 ring heteroatoms selected from —N═ or —NR—; a substituted or unsubstituted (C1-C8)alkylene-cyclic (C5-C6)alkylene group which is optionally interrupted with —N═ or —NR—; a substituted or unsubstituted (C1-C8)alkylene-(C5-C6)arylene group which is optionally interrupted with —N═ or —NR—; a substituted or unsubstituted cyclic (C5-C6)alkylene-(C1-C8)alkylene group which is optionally interrupted with —O—, —N═ or —NR—; a substituted or unsubstituted (C5-C6)arylene-(C1-C8)alkylene group which is optionally interrupted with —O—, —N═ or —NR—; or a heteroatom selected from —O— or —NR—;

R₂, R₃, R₄ and R₅ are each independently selected from a substituted or unsubstituted, saturated or unsaturated, straight or branched chain (C1-C8)hydrocarbyl group optionally interrupted with 1, 2 or 3 heteroatom(s) selected from —O—, —N═ or —NR—;

R₆ is selected from a substituted or unsubstituted, saturated or unsaturated, straight or branched chain (C1-C8)alkylene group optionally interrupted with 1, 2, or 3 heteroatom(s) selected from —O—, —N═ or —NR—; a substituted or unsubstituted, unsaturated or partially saturated cyclic (C5-C6)alkylene group optionally having 1, 2 or 3 ring heteroatoms selected from —N═ or —NR—; a substituted or unsubstituted cyclic (C5-C6)arylene group optionally having 1, 2 or 3 ring heteroatoms selected from —N═ or —NR—; a substituted or unsubstituted (C1-C8)alkylene-cyclic (C5-C6)alkylene group which is optionally interrupted with —N═ or —NR—; a substituted or unsubstituted (C1-C8)alkylene-(C5-C6)arylene group which is optionally interrupted with —N═ or —NR—; a substituted or unsubstituted cyclic (C5-C6)alkylene-(C1-C8)alkylene group which is optionally interrupted with —O—, —N═ or —NR—; a substituted or unsubstituted (C5-C6)arylene-(C1-C8)alkylene group which is optionally interrupted with —O—, —N═ or —NR—;

and

wherein the number of optional substituent(s) of each of R₁ to R₆ is independently selected from 1 or 2; and the optional substituent(s) of each R₁ to R₆ are independently selected from saturated or unsaturated, straight or branched chain (C1-C8)hydrocarbyl group optionally interrupted with 1, 2 or 3 heteroatom(s) selected from —O—, —N═ or —NR—; a substituted or unsubstituted, unsaturated or partially saturated cyclic (C5-C6)hydrocarbyl group optionally having 1, 2 or 3 ring heteroatoms selected from —N═ or —NR—; a substituted or unsubstituted (C5-C6)aryl group optionally having 1, 2 or 3 ring heteroatoms selected from —O—, —N═ or —NR—; or ═O group; or —N(R)₂;

R is independently selected from H or linear (C1-C6)alkyl group; and

n is 2 to 20.

In one preferable embodiment of HALS compound (A), or of any of the above or below preferable subgroup thereof, R₆ is linked to ring N atom via —CH₂—.

In one preferable embodiment of HALS compound (A), or of any of the above or below preferable subgroup thereof, n is preferably 3 to 15, preferably 4 to 15, preferably 5 to 15, more preferably 6 to 15, more preferably 8 to 15, more preferably 10 to 15.

More preferably, HALS compound (A), or any of the above or below preferable subgroup thereof, meets, in any combination and in any order, one or more, or all of the below substituent definition(s) 1) to 4):
1) R₁ is preferably —O—;
2) Each of R₂, R₃, R₄ and R₅ independently are preferably linear (C1-C6)alkyl group, preferably linear (C1-C4)alkyl group preferably a methyl group, more preferably each are the same and are preferably linear (C1-C6)alkyl group, preferably linear (C1-C4)alkyl group, most preferably a methyl group;
3) R₆ is preferably —(CH₂)ₓ—O—(C═O)—(CH₂)_{y}—(C═O), wherein x is 1 to 6 preferably 1 to 4, preferably 1 to 2 and y is 1 to 6 preferably 1 to 4, preferably 1 to 2, most preferably —(CH₂)₂—O—(C═O)—(CH₂)₂—(C═O); and/or
4) n is preferably 3 to 15, preferably 4 to 15, preferably 5 to 15, more preferably 6 to 15, more preferably 8 to 15, more preferably 10 to 15.

More preferably, HALS compound (A), or any of the above or below preferable subgroup thereof, meets all of the above substituent definition(s) 1) to 4).

In the most preferred embodiment the HALS compound (A) is of formula (A5), wherein
R₁ is —O—;
each of R₂, R₃, R₄ and R₅ independently are methyl;
R₆ is —CH₂—CH₂—O—C(═O)—CH₂—CH₂—C(C═O)—; and
n is 3 to 15, preferably 4 to 15, preferably 5 to 15, more preferably 6 to 15, more preferably 8 to 15, more preferably 10 to 15.

In a preferable embodiment of the HALS compound (A), or any of the above or below preferable subgroup thereof, wherein the end groups terminating the unit of formula (A0) are: end group R₇ which is linked to R₁ and which is —H group; and R₈ which is linked to R₆ and which is —OH group. Accordingly, the HALS compound (A) is preferably a compound of formula (A6):

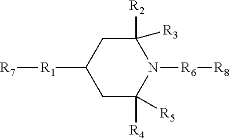

wherein R1 to R6 are as defined above or in claims, including the preferable subgroups, in any order; and R₇ is —H group and R₈ is —OH group.

HALS of formula (A) and any subgroups thereof is preferably produced by a condensation polymerization, wherein H₂O is removed during the reaction of the monomers.

HALS of formula (A) can be produced in a manner known in the chemical literature or can be commercially available.

One of the preferred HALS of formula (A) has a cas number 65447-77-0. The chemical name of said HALS of formula (A) is Butanedoic acid, dimethylester, polymer with 4-hydroxy-2,2,6,6 tetramethyl-1-piperidine ethanol. Such compound is commercially available by many suppliers with variable commercial names depending on the supplier.

The amount of the HALS (A) is preferably of 0.01 to 1.0 wt %, preferably 0.01 to 0.5 wt %, preferably 0.02 to 0.4 wt %, preferably 0.03 to 0.3 wt %, preferably 0.05 to 0.25 wt %, based on the amount of the polymer composition (100 wt %).

It is preferred that the polymer composition as defined above or below only includes one or more, more preferably one hindered amine compound (HALS) as defined above or below. Hindered amine compounds (HALS) not falling under the definition as described above or below are preferably not included into the polymer composition as defined above or below.

Preferably, the polymer (P) is a polyethylene polymer.

The silane group(s) containing units (b) can be present
as a comonomer of the polymer (P),
as a compound grafted chemically to the polymer (P), or
as a separate component in the polymer composition.

Preferably, the silane group(s) containing units are incorporated to the polymer (P)
as a comonomer of the polymer (P), or
as a compound grafted chemically to the polymer (P).

Accordingly, in one preferable embodiment the polymer (P) is
a polymer of ethylene (a) which is selected from
(a1) a polymer of ethylene which bears silane group(s) containing comonomer;
(a2) a copolymer of ethylene with one or more polar comonomer(s) selected from (C1-C6)-alkyl acrylate or (C1-C6)-alkyl (C1-C6)-alkylacrylate comonomer(s), which copolymer (a2) bears silane group(s) containing units and which copolymer (a2) is different from the polymer of ethylene (a1); or
(a3) a copolymer of ethylene with one or more (C1-C10)-alpha-olefin comonomer which is different from polymer of ethylene (a1) and polymer of ethylene (a2).

The polymer of ethylene (a), as defined above, below or in claims, is referred herein also shortly as “polymer (a)”.

The definition (a1) a polymer of ethylene which bears silane group(s) containing comonomer, as defined above, below or in claims, is referred herein also shortly as “polymer of ethylene (a1)” or “polymer (a1)”.

The definition (a2) a copolymer of ethylene with one or more polar comonomer(s) selected from (C1-C6)-alkyl acrylate or (C1-C6)-alkyl (C1-C6)-alkylacrylate comonomer(s), which copolymer (a2) bears silane group(s) containing units and which copolymer (a2) is different from the polymer of ethylene (a1), as defined above, below or in claims, is referred herein also shortly as “copolymer of ethylene (a2)”, “copolymer (a2)” or “polymer (a2)”.

The definition (a3) a copolymer of ethylene with one or more (C1-C10)-alpha-olefin comonomer which is different from polymer of ethylene (a1) and polymer of ethylene (a2), as defined above, below or in claims, is referred herein also shortly as “polymer (a3)”.

As well known “comonomer” refers to copolymerisable comonomer units.

Accordingly, in case of silane group(s) containing units are incorporated to the polymer (a) as a comonomer, the silane group(s) containing units are copolymerized as comonomer with ethylene monomer during the polymerization process of polymer (a). In case the silane group(s) containing units are incorporated to the polymer by grafting, the silane group(s) containing units are reacted chemically (also called as grafting), with the polymer (a) after the polymerization of the polymer (a). The chemical reaction, i.e. grafting, is performed typically using a radical forming agent such as peroxide. Such chemical reaction may take place before or during the lamination process of the invention. In general, copolymerisation and grafting of the silane group(s) containing units to ethylene are well known techniques and well documented in the polymer field and within the skills of a skilled person.

It is also well known that the use of peroxide in the grafting embodiment decreases the melt flow rate (MFR) of an ethylene polymer due to a simultaneous crosslinking reaction. As a result, the grafting embodiment can bring limitation to the choice of the MFR of polymer (a) as a starting polymer, which choice of MFR can have an adverse impact on the quality of the polymer at the end use application. Furthermore, the by-products formed from peroxide during the grafting process can have an adverse impact on use life of the polymer composition at end use application.

Thus preferably, the silane group(s) containing units are present in polymer (a) as a comonomer. I.e. in case of polymer (a1) the silane group(s) containing units are copolymerised as a comonomer together with the ethylene monomer during the polymerisation process of the polymer (a1). And in case of the polymer (a2) the silane group(s) containing units are copolymerised as a comonomer together with the polar comonomer and ethylene monomer during the polymerisation process of polymer (a2).

“Silane group(s) containing comonomer” means herein above, below or in claims that the silane group(s) containing units are present as a comonomer.

The silane group(s) containing unit or, preferably, the silane group(s) containing comonomer, of polymer of ethylene (a), is preferably a hydrolysable unsaturated silane compound represented by the formula (I):

R1SiR2qY3-q (I)

wherein

R1 is an ethylenically unsaturated hydrocarbyl, hydrocarbyloxy or (meth)acryloxy hydrocarbyl group,

each R2 is independently an aliphatic saturated hydrocarbyl group,

Y which may be the same or different, is a hydrolysable organic group and

q is 0, 1 or 2.

Further suitable silane group(s) containing unit, preferably comonomer, is e.g. gamma-(meth)acryl-oxypropyl trimethoxysilane, gamma(meth)acryloxypropyl triethoxysilane, and vinyl triacetoxysilane, or combinations of two or more thereof.

One suitable subgroup of silane compound of formula (I) is an unsaturated silane compound or, preferably, comonomer of formula (II)

CH2=CHSi(OA)3 (II)

wherein each A is independently a hydrocarbyl group having 1-8 carbon atoms, suitably 1-4 carbon atoms.

When the silane group(s) containing units are incorporated to the final polymer (a) as a comonomer, preferably as a comonomer of formula (I), preferably of formula (II), then the unsaturation, preferably vinyl functionality, of said comonomer is incorporated into the polymer via radical polymerisation process, whereby two C atoms of said comonomer become part of the backbone of the final polymer (a), as well known to a skilled person. Whereas in grafting the polymer (a) is first polymerised to a polymer and the final polymer is attained by grafting, with peroxide, the silane group(s) containing units, preferably as a silane compound of formula (I), preferably of formula (II), whereby one of the C atoms of the vinyl unsaturation is attached to the polymer backbone, as well known to a skilled person. Therefore the branch which the silane group(s) is attached to is one carbon atom shorter compared to the branch formed by grafting as evident for a skilled person in the polymer filed. This will have the implication that the grafted silane extends further out from the polymer backbone and becomes more accessible for reaction than for a copolymerized polymer.

Moreover, the copolymerisation of the silane group(s) containing units as a comonomer into the polymer backbone provides more uniform incorporation of the units compared to grafting of the units. The copolymerized silane groups is distributed depending on the reactivity ratio between silane, ethylene and other monomer while the grafting process is providing a polymer where the silane groups cannot be incorporated with any controlled distribution. In other words, when the silane group(s) containing units are incorporated as a comonomer to the polymer backbone of the polyolefin copolymer, preferably of the polyethylene copolymer, then the formed copolymer is a uniform “random copolymer” which term has a well-known meaning compared to more uneven distribution of the grafted silane group(s) containing units. Furthermore, compared to grafting, the copolymerisation does not require the addition of peroxide after production of the polymer.

The silane group(s) containing unit, or preferably, the comonomer, of the invention, is preferably the compound of formula (II) which is vinyl trimethoxysilane, vinyl bismethoxyethoxysilane, vinyl triethoxysilane, more preferably vinyl trimethoxysilane or vinyl triethoxysilane, more preferably vinyl trimethoxysilane, comonomer.

The amount (mol %) of the silane group(s) containing units present, preferably present as comonomer, in the polymer (a) is preferably of 0.01 to 2.0 mol %, preferably 0.01 to 1.00 mol %, suitably from 0.05 to 0.80 mol %, suitably from 0.10 to 0.60 mol %, suitably from 0.10 to 0.50 mol %, when determined according to “Comonomer contents” as described below under “Determination Methods”.

In one embodiment (A1) of the polymer (a), the polymer (a) is a polymer of ethylene which bears silane group(s) containing comonomer (a1). In this embodiment (A1) of the polymer (a), the polymer (a1) does not contain, i.e. is without, a polar comonomer as defined for polymer (a2). Preferably the silane group(s) containing comonomer is the sole comonomer present in the polymer (a1). Accordingly, the polymer (a1) is preferably produced by copolymerising ethylene monomer in a high pressure polymerization process in the presence of silane group(s) containing comonomer using a radical initiator. Preferably the silane group(s) containing comonomer is the only comonomer present in the polymer of ethylene (a1). In said one preferable embodiment (A1) of the polymer (a), the polymer (a1) is preferably a copolymer of ethylene with silane group(s) containing comonomer according to formula (I), more preferably with silane group(s) containing comonomer according to formula (II), more preferably with silane group(s) containing comonomer according to formula (II) selected from vinyl trimethoxysilane, vinyl bismethoxyethoxysilane, vinyl triethoxysilane or vinyl trimethoxysilane comonomer, as defined above or in claims. Most preferably the polymer (a1) is a copolymer of ethylene with vinyl trimethoxysilane, vinyl bismethoxyethoxysilane, vinyl triethoxysilane or vinyl trimethoxysilane comonomer, preferably with vinyl trimethoxysilane or vinyl triethoxysilane comonomer, most preferably vinyl trimethoxysilane comonomer.

In another embodiment (A2) of the polymer (a), the polymer (a) is a copolymer of ethylene with one or more polar comonomer(s) selected from (C1-C6)-alkyl acrylate or (C1-C6)-alkyl (C1-C6)-alkylacrylate comonomer(s) (a2), which copolymer (a2) bears silane group(s) containing units. In this embodiment (A2) of the polymer (a) the polymer (a2) is a copolymer of ethylene with one or more, preferably one, polar comonomer(s) selected from (C1-C6)-alkyl acrylate or (C1-C6)-alkyl (C1-C6)-alkylacrylate comonomer(s) and silane group(s) containing comonomer. Preferably, the polar comonomer of the polymer of ethylene (a2) is selected from one of (C1-C6)-alkyl acrylate comonomer, preferably from methyl acrylate, ethyl acrylate or butyl acrylate comonomer. More preferably, the polymer (a2) is a copolymer of ethylene with a polar comonomer selected from methyl acrylate, ethyl acrylate or butyl acrylate comonomer and with silane group(s) containing comonomer. The polymer (a2) is most preferably a copolymer of ethylene with a polar comonomer selected from methyl acrylate, ethyl acrylate or butyl acrylate comonomer and with silane group(s) containing comonomer of compound of formula (I). Preferably, in this embodiment the polar comonomer and the preferable silane group(s) containing comonomer are the only comonomers present in the copolymer of ethylene (a2).

In another embodiment (A3) of the polymer (a), the polymer (a) is the polymer (a3) which preferably is a polymer of ethylene with one or more, preferably one, comonomer(s) selected from (C1-C8)-alpha-olefin comonomer.

Most preferably the polymer (a) is selected from polymer (a1) or (a2).

The content of the polar comonomer present in the polymer (a2) is preferably of 0.5 to 30.0 mol %, 2.5 to 20.0 mol %, preferably of 4.5 to 18 mol %, preferably of 5.0 to 18.0 mol %, preferably of 6.0 to 18.0 mol %, preferably of 6.0 to 16.5 mol %, more preferably of 6.8 to 15.0 mol %, more preferably of 7.0 to 13.5 mol %, when measured according to “Comonomer contents” as described below under the “Determination methods”.

In said another preferable embodiment (A2) of the polymer (a), the polymer (a2) is preferably a copolymer of ethylene with the polar comonomer, as defined above, below or in claims, and with silane group(s) containing comonomer according to formula (I), more preferably with silane group(s) containing comonomer according to formula (II), more preferably with silane group(s) containing comonomer according to formula (II) selected from vinyl trimethoxysilane, vinyl bismethoxyethoxysilane, vinyl triethoxysilane or vinyl trimethoxysilane comonomer, as defined above or in claims. Preferably the polymer (a2) is a copolymer of ethylene with methyl acrylate, ethyl acrylate or butyl acrylate comonomer and with vinyl trimethoxysilane, vinyl bismethoxyethoxysilane, vinyl triethoxysilane or vinyl trimethoxysilane comonomer, preferably with vinyl trimethoxysilane or vinyl triethoxysilane comonomer. More preferably the polymer (a2) is a copolymer of ethylene with methyl acrylate comonomer and with vinyl trimethoxysilane, vinyl bismethoxyethoxysilane, vinyl triethoxysilane or vinyl trimethoxysilane comonomer, preferably with vinyl trimethoxysilane or vinyl triethoxysilane comonomer more preferably with vinyl trimethoxysilane.

Accordingly, the polymer (a2) is most preferably a copolymer of ethylene with methyl acrylate comonomer together with silane group(s) containing comonomer as defined above, below or in claims, preferable a copolymer of ethylene with methyl acrylate comonomer and with vinyl trimethoxysilane or vinyl triethoxysilane comonomer, preferably with methyl acrylate comonomer and with vinyl trimethoxysilane comonomer.

Without binding to any theory, methyl acrylate (MA) is the only acrylate which cannot go through the ester pyrolysis reaction, since does not have this reaction path. Therefore, the polymer (a2) with MA comonomer does not form any harmful acid (acrylic acid) degradation products on the polymer backbone at high temperatures, whereby polymer (a2) of ethylene and methyl acrylate comonomer contribute to good quality and life cycle of the end article thereof. This is not the case e.g. with vinyl acetate units of EVA, since EVA forms harmful acetic acid degradation products at high temperatures. Moreover, the other acrylates like ethyl acrylate (EA) or butyl acrylate (BA) can go through the ester pyrolysis reaction, and if degrade, could form volatile olefinic by-products and result in an acidic group on the polymer backbone.

The polymer (a) present in the at least one layer of the layer element (LE), enables, if desired, to decrease the MFR of the polymer (a) compared to prior art and thus offers higher resistance to flow during the production of the preferable layer element (LE) of the invention. As a result, the preferable MFR can further contribute, if desired, to the quality of the layer element (LE), and to an article thereof comprising the layer element (LE).

The melt flow rate, MFR₂, of the polymer composition, preferably of polymer (a), is preferably less than 20 g/10 min, preferably less than 15 g/10 min, preferably from 0.1 to 13 g/10 min, preferably from 0.2 to 10 g/10 min, preferably from 0.3 to 8 g/10 min, more preferably from 0.4 to 6, g/10 min (according to ISO 1133 at 190° C. and at a load of 2.16 kg).

The preferable MFR of the polymer composition, preferably of the polymer (a) can further contribute, if desired, to the quality of the preferable layer element (LE), to an article, preferably to an article comprising the preferable layer element (LE), of the invention. Moreover, the polymer (a) of the invention can have, if desired, low MFR, for instance lower MFR than that conventionally used in the field of photovoltaic (PV) modules, since the polymer (a) has advantageous flowability and processability properties combined with highly feasible adhesion properties.

The composition, preferably the polymer (a), preferably has a melting temperature, Tm, of 120° C. or less, preferably 110° C. or less, more preferably 100° C. or less and most preferably 95° C. or less, when measured according to ASTM D3418 as described under “Determination Methods”. Preferably the melting temperature of the composition, more preferably the polymer (a) is 70° C. or more, more preferably 75° C. or more, even more preferably 78° C. or more, when measured as described below under “Determination Methods”. The preferable melting temperature is beneficial for instance for a lamination process of the preferable layer element (LE) of the invention, since the time of the melting/softening step can be reduced.

Typically, and preferably, the density of the composition, preferably of the polymer of ethylene (a), of the interlayer element is higher than 860 kg/m3. Preferably the density is not higher than 970 kg/m3, and preferably is from 920 to 960 kg/m3, according to ISO 1872-2 as described below under “Determination Methods”.

Preferred polymer (a) is a polymer of ethylene (a1) with vinyl trimethoxysilane comonomer or a copolymer of ethylene (a2) with methylacrylate comonomer and with vinyl trimethoxysilane comonomer. The most preferred polymer (a) is a copolymer of ethylene (a2) with methylacrylate comonomer and with vinyl trimethoxysilane comonomer.

The polymer (a) of the composition can be e.g. commercially available or can be prepared according to or analogously to known polymerization processes described in the chemical literature.

In a preferable embodiment the polymer (a), i.e. polymer (a1) or (a2), is produced by polymerising ethylene suitably with silane group(s) containing comonomer (=silane group(s) containing units present as comonomer) as defined above, and in case of polymer (a2) also with the polar comonomer(s), in a high pressure (HP) process using free radical polymerization in the presence of one or more initiator(s) and optionally using a chain transfer agent (CTA) to control the MFR of the polymer. The HP reactor can be e.g. a well-known tubular or autoclave reactor or a mixture thereof, suitably a tubular reactor. The high pressure (HP) polymerisation and the adjustment of process conditions for further tailoring the other properties of the polymer, depending on the desired end application, are well known and described in the literature, and can readily be used by a skilled person. Suitable polymerisation temperatures range up to 400° C., suitably from 80 to 350° C. and pressure from 70 MPa, suitably 100 to 400 MPa, suitably from 100 to 350 MPa. The high pressure polymerization is generally performed at pressures of 100 to 400 MPa and at temperatures of 80 to 350° C. Such processes are well known and well documented in the literature and will be further described later below.

The incorporation of the comonomer(s), when present, including the preferred form of silane group(s) containing units as comonomer, to the ethylene monomer and the control of the comonomer feed to obtain the desired final content of said comonomer(s) can be carried out in a well-known manner and is within the skills of a skilled person.

Further details of the production of ethylene (co)polymers by high pressure radical polymerization can be found i.a. in the Encyclopedia of Polymer Science and Engineering, Vol. 6 (1986), pp 383-410 and Encyclopedia of Materials: Science and Technology, 2001 Elsevier Science Ltd.: “Polyethylene: High-pressure, R. Klimesch, D. Littmann and F.-O. Mahling pp. 7181-7184.

Such HP polymerisation results in a so called low density polymer of ethylene (LDPE), herein results in polymer (a1) or polymer (a2). The term LDPE has a well-known meaning in the polymer field and describes the nature of polyethylene produced in HP, i.e. the typical features, such as different branching architecture, to distinguish the LDPE from PE produced in the presence of an olefin polymerisation catalyst (also known as a coordination catalyst). Although the term LDPE is an abbreviation for low density polyethylene, the term is understood not to limit the density range, but covers the LDPE-like HP polyethylenes with low, medium and higher densities.

The polymer (a3) can be commercially available or be produced in a polymerization process using a coordination catalyst, typically Ziegler-Natta or single site catalyst, as well documented in the literature. The choice of the process, process conditions and the catalyst is within the skills of a skilled person.

Below, the amounts “Based on the amount of the polymer composition of the invention (100 wt %)” means that the amounts of the components present in the polymer composition of the invention total to 100 wt %.

In one embodiment, the composition of the invention suitably comprises additive(s) different from the HALS (A). Preferably the composition comprises, based on the total amount (100 wt %) of the composition,
0.0001 to 10.0 wt % of additives, preferably 0.0001 and 5.0 wt %, like 0.0001 and 2.5 wt %, of the additives different from the HALS (A), and optionally
0 to 40.0 wt % pigment.

Pigment, if present, is preferably in an amount of 0.10 to 40.0 wt %, suitably from 0.20 to 40.0 wt %, preferably from 0.3 to 30.0 wt %, preferably from 0.3 to 25.0 wt %, preferably from 0.30 to 20.0 wt %, more preferably from 0.30 to 15.0 wt %.

The optional pigment is preferably selected from an inorganic pigment, preferably from an inorganic white pigment. More preferably, the optional pigment is a titanium dioxide, TiO₂. The titanium dioxide, TiO₂, is preferably in a form of rutile. Rutile is a mineral which is primarily based on titanium dioxide and has a tetragonal unit cell structure as well known in the art.

In one preferable embodiment the polymer composition comprises, preferably consists of,
a polymer (P) which bears silane group(s) containing units;
a HALS (A) in an amount of 0.01 to 1.0 wt % based on the amount of the polymer composition (100 wt %); and
optionally additives, preferably 0.0001 to 10 wt % of additives, preferably 0.0001 and 5.0 wt %, like 0.0001 and 2.5 wt %, of additives different from the HALS (A).

Naturally, the preferable additives are also different from polymer (a) or the optional pigment.

The optional additives other than HALS (A) or optional pigment are e.g. conventional additives suitable for the desired end application and within the skills of a skilled person, including without limiting to, preferably at least antioxidant(s), UV light stabilizer(s) and/or UV light absorbing agents, and may also include metal deactivator(s), clarifier(s), brightener(s), acid scavenger(s) as well as slip agent(s) etc. The optional additives preferably do not include any phosphite containing additives. The optional antioxidant(s) usually do not include sterically hindered phenol antioxidants. Each additive can be used e.g. in conventional amounts, the total amount of additives present in the polymer composition of the invention being preferably as defined above. Such additives are generally commercially available and are described, for example, in “Plastic Additives Handbook”, 5th edition, 2001 of Hans Zweifel.

In a preferable embodiment the polymer composition consists of the polymer (a) as the only polymeric component(s). “Polymeric component(s)” exclude herein any carrier polymer(s) of HALS, optional additive or optional pigment, e.g. carrier polymer(s), if any of HALS, optional additive or optional pigment are present in a so called master batch(es) in the composition. Such optional carrier polymer(s) are calculated to the amount of the respective HALS, additive and/or pigement, based on the amount of the polymer composition(100 wt %).

The polymer composition, preferably the polymer (a), can be crosslinked, if desired. The polymer composition, preferably the polymer (a), is preferably not crosslinked using peroxide. Preferably, the polymer composition is peroxide-free.

If desired, depending on the end application, the polymer composition of an article, preferably the polymer composition, preferably the polymer (a), of the layer element (LE), can be crosslinked via silane group(s) containing units using a silanol condensation catalyst (SCC), which is preferably selected from the group of carboxylates of tin, zinc, iron, lead or cobalt or aromatic organic sulphonic acids, before or during the lamination process of the invention. Such SCCs are for instance commercially available.

It is to be understood that the SCC as defined above are those conventionally supplied for the purpose of crosslinking.

The silanol condensation catalyst (SCC), which can optionally be present in the polymer composition, preferably in the polymer composition of the layer element (LE), is more preferably selected from the group C consisting of carboxylates of metals, such as tin, zinc, iron, lead and cobalt; from a titanium compound bearing a group hydrolysable to a Brönsted acid (preferably as described in WO 2011/160964 of Borealis, included herein as reference), from organic bases; from inorganic acids; and from organic acids; suitably from carboxylates of metals, such as tin, zinc, iron, lead and cobalt, from a titanium compound bearing a group hydrolysable to a Brönsted acid or from organic acids, preferably from dibutyl tin dilaurate (DBTL), dioctyl tin dilaurate (DOTL), particularly DOTL; or an aromatic organic sulphonic acid, which is suitably an organic sulphonic acid which comprises the structural element:

Ar(SO₃H)x (III)

wherein Ar is an aryl group which may be substituted or non-substituted, and if substituted, then suitably with at least one hydrocarbyl group up to 50 carbon atoms, and x is at least 1; or a precursor of the sulphonic acid of formula (III) including an acid anhydride thereof or a sulphonic acid of formula (III) that has been provided with a hydrolysable protective group(s), e.g. an acetyl group that is removable by hydrolysis. Such organic sulphonic acids are described e.g. in EP736065, or alternatively, in EP1309631 and EP1309632.

The amount of the optional crosslinking agent (SCC), if present, is preferably of 0 to 0.1 mol/kg, like 0.00001 to 0.1, preferably of 0.0001 to 0.01, more preferably 0.0002 to 0.005, more preferably of 0.0005 to 0.005, mol/kg polymer of ethylene (a). Preferably no crosslinking agent (SCC) is present in the polymer composition.

In a preferable embodiment of the invention, no silane condensation catalyst (SCC), which is selected from the SCC group of group C consisting of tin-organic catalysts or aromatic organic sulphonic acids, is present in polymer composition. In a further preferable embodiment no peroxide or silane condensation catalyst (SCC), as defined above, is present in the polymer composition. I.e. preferably the polymer composition is peroxide-free and “silane condensation catalyst (SCC) of group C”—free. As already mentioned, with the present polymer composition of the invention, crosslinking of the polymer composition using conventional SCC or peroxide, as mentioned above, below or in claims, can be avoided, which contributes to achieve the good quality of the end applications thereof, for instance of the layer element (LE) of the invention.

The invention provides a use of the polymer composition according to any of the preceding claims for producing a layer element (LE) comprising one or more layer(s), which comprise the polymer composition.

The invention also provides a use of the polymer composition for producing an article comprising the layer element (LE).

Layer Element (LE)/Article of the Invention and End Applications Thereof

The invention also provides a layer element (LE) comprising one or more layers, wherein at least one layer, comprises, preferably consists of, the polymer composition of the invention comprising
a polymer (P);
silane group(s) containing units (b); and
a hindered amine compound (HALS) comprising a unit of formula (A0); as defined above and in claims.

The layer element (LE) is preferably selected from
a monolayer element comprising the polymer composition as defined above, below or in claims, or
a multilayer element wherein at least one layer comprises the polymer composition as defined above, below or in claims.

Preferably, one or more layer(s) of the layer element (LE) of the invention consist(s) of the polymer composition of the invention. More preferably one layer of the layer element (LE) comprises, preferably consists of, the polymer composition. One preferable layer element (LE) is a monolayer element comprising, preferably consisting of the polymer composition of the invention.

The invention also provides an article comprising the polymer composition of the invention.

Preferably the article comprises a layer element (LE) which comprises, preferably consists of, the polymer composition of the invention comprising
a polymer (P);
silane group(s) containing units (b); and
a hindered amine compound (HALS) comprising a unit of formula (A0); as defined above and in claims.

The layer element (LE) can be part of an article, e.g. a layer of any shape in moulded article, like bottle or container, such as a label is said article; or the article is, i.e. consists of, the layer element (LE), which is for instance a mono or multilayer film for packaging or thermoforming; or the article is an assembly of two or more layer elements, wherein at least one layer element is the layer element (LE) of the invention.

It is to be understood that the part or each of the layer elements of the assembly of the invention typically, and preferably, provide a different functionality into said assembly.

The preferred layer element (LE), preferably of the layer element (LE) of the article, is a monolayer element comprising, preferably consisting of, the polymer composition as defined above, below or in claims.

The article is preferably an assembly comprising two or more layer elements, wherein at least one layer element is the layer element (LE). A photovoltaic (PV) module is one example of such assembly which comprises layer elements of different functionalities.

Another non-limiting example of the article as an assembly is an article for construction applications, like elements in buildings, for instance architectural elements, such as exterior/interior elements, like facades outside the building, window elements, door elements or indoor wall elements etc.; for elements in bridges; for elements in vehicles, such as windows etc. in cars, trains, airplanes or ships; for elements in production equipments, like safety windows in machines etc.; for elements in production equipments, like safety windows in machines; for elements in household devices; for projection applications, like head-up displays, or for elements in furniture etc.; not limiting to above mentioned applications, comprising the layer element (LE) as defined above, below or in claims. FIG. 2 illustrates such other embodiment of the assembly of the article which is a laminated glass element e.g. for safety, insulation or thermal applications, which all have a well-known meaning. In FIG. 2 the laminated glass element comprises a first layer element (1), a layer element (LE) of the invention comprising the polymer composition of the invention and a second layer element (2).

The article, the preferable assembly, is preferably a photovoltaic (PV) module comprising a photovoltaic element and one or more further layer elements, wherein at least one layer element is the layer element (LE) of the invention comprising, preferably consisting of, the polymer composition which comprises
a polymer (P);
silane group(s) containing units (b); and
a hindered amine compound (HALS) comprising a unit of formula (A0); as defined above and in claims.

Preferably the photovoltaic (PV) module of the invention comprises, in the given order, a protective front layer element, a front encapsulation layer element, a photovoltaic element, a rear encapsulation layer element and a protective back layer element, wherein at least one layer element is the layer element (LE) of the invention.

It is to be understood herein that the protective front layer element and the front encapsulation layer element of the PV module are on the light receiving side of the photovoltaic (PV) module.

The protective back layer element is referred herein also as backsheet layer element. The “photovoltaic element” means that the element has photovoltaic activity. The photovoltaic element can be e.g. an element of photovoltaic cell(s), which has a well-known meaning in the art. Silicon based material, e.g. crystalline silicon, is a non-limiting example of materials used in photovoltaic cell(s). Crystalline silicon material can vary with respect to crystallinity and crystal size, as well known to a skilled person. Alternatively, the photovoltaic element can be a substrate layer on one surface of which a further layer or deposit with photovoltaic activity is subjected, for example a glass layer, wherein on one side thereof an ink material with photovoltaic activity is printed, or a substrate layer on one side thereof a material with photovoltaic activity is deposited. For instance, in well-known thin film solutions of photovoltaic elements e.g. an ink with photovoltaic activity is printed on one side of a substrate, which is typically a glass substrate.

The photovoltaic element is most preferably an element of photovoltaic cell(s). “Photovoltaic cell(s)” means herein a layer element(s) of photovoltaic cells, as explained above, together with connectors.

The PV module may optionally comprise a protective cover as a further layer element after the backsheet layer element, in the given order, which can be e.g. a metal frame, such as aluminium frame (with junction box).

All said terms have a well-known meaning in the art.

The materials of the above elements other than the polymer composition of the layer element (LE) are well known in the prior art and can be chosen by a skilled person depending on the desired PV module.

As well known, the elements and the layer structure of the photovoltaic module of the invention can vary depending on the desired type of the PV module. The photovoltaic module can be rigid or flexible. The rigid photovoltaic module can for example contain a rigid protective front layer element, such as a glass element, a front encapsulation layer element, a photovoltaic layer element, a rear encapsulation layer element and a backsheet layer element which can be rigid or flexible. In flexible modules all the above elements are flexible, whereby the protective front and back as well as the front and rear encapsulation layer elements are typically based on polymeric layer elements.

Moreover, any of the above layer elements of the PV module can be a monolayer element or a multilayer element. Preferably, at least one, or both, of the front and back encapsulation layer element of the PV module is/are encapsulation monolayer element(s).

Most preferable embodiment of the photovoltaic (PV) module as the article of the invention is a photovoltaic (PV) module comprising, in the given order, a protective front layer element, a front encapsulation layer element, a photovoltaic element, a rear encapsulation layer element and a protective back layer element, wherein the front encapsulation layer element or the rear encapsulation layer element, or both of the front encapsulation layer element and the rear encapsulation layer element, is/are the layer element (LE) of the invention.

In this embodiment the other layer elements of the PV module preferably comprise, preferably consist of, a different polymer compositions than the polymer composition of the invention.

More preferably, the front encapsulation layer element and the rear encapsulation element preferably comprise, preferably consist of, the layer element (LE), which is preferably a monolayer element comprising, preferably consisting of, the composition of the invention.

As a non-limiting example only, the thickness of the front and rear encapsulation layer element is typically up to 2 mm, preferably up to 1 mm, typically 0.3 to 0.6 mm.

As a non-limiting example only, the thickness of the rigid protective front layer element, e.g. glass layer, is typically up to 10 mm, preferably up to 8 mm, preferably 2 to 4 mm. As a non-limiting example only, the thickness of the flexible protective front layer element, e.g. polymeric (multi)layer element, is typically up to 700, like 90 to 700, suitably 100 to 500, such as 100 to 400, μm.

As a non-limiting example only, the thickness of a photovoltaic element, e.g. an element of monocrystalline photovoltaic cell(s), is typically between 100 to 500 microns.

In some embodiments there can be an adhesive layer between the different layer elements of an assembly, preferably of a PV module of the invention, and/or between the layers of a multilayer element of layer element(s), like the layer element (LE), as well known in the art. Such adhesive layers have the function to improve the adhesion between the two elements and have a well-known meaning in the lamination field. The adhesive layers are differentiated from the other functional layer elements of the PV module, e.g. those as specified above, below or in claims, as evident for a skilled person in the art. Preferably, there is no adhesive layer between the protective front layer element and the front encapsulation layer element and/or, preferably, no adhesive layer between the protective back layer element and the rear encapsulation layer element. Preferably, there is no adhesive layer between the layer element (LE) as the front encapsulation element and the photovoltaic element of the PV module. Preferably, there is no adhesive layer between the layer element (LE) as the rear encapsulation element and the photovoltaic element of the PV module. Further preferably, there is no adhesive layer(s) between the layers of optional multilayer element of the layer element (LE). In one preferable embodiment the layer element (LE) is a monolayer element.

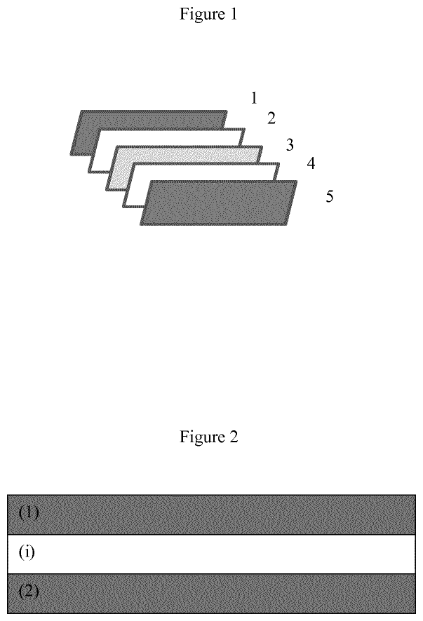

FIG. 1 is a schematic picture of one example of a preferred PV module of the invention comprising a protective front layer element (1), a front encapsulation layer element (2), a photovoltaic element (3), a rear encapsulation layer element (4) and the protective back layer element (5). In one preferable embodiment the rear encapsulation layer element (4) or the front encapsulation layer element (2), or, and preferably, the front encapsulation layer element (2) and the rear encapsulation layer element (4), comprise(s), preferably consist(s) of, the polymer composition of the invention.

The separate layer elements of PV module can be produced in a manner well known in the photovoltaic field or from the literature; or are already commercially available as layer elements for PV modules. The PV layer element of the layer element (LE), preferably the layer element (LE) as the front encapsulation layer element, and preferably as the rear encapsulation layer element, can be produced as described below.

It is also to be understood that part of the layer elements can be in integrated form, i.e. two or more of said PV elements can be integrated together, e.g. by lamination, before subjecting to the below described preferable lamination process of the invention.

For example, if desired, the rear encapsulation layer element can be integrated to the protective back layer element (i.e. to the backsheet layer element) by extrusion, or lamination or by any combination thereof, before the layer elements of the PV module are arranged to an assembly and said PV elements of the assembly are integrated, typically laminated, together.

The invention further provides a process for producing a layer element (LE), wherein the layer element (LE) is produced by extrusion using typically a conventional extruder as described in the literature. The choice of the extrusion conditions are within the skills of a skilled person. Preferably the monolayer or multilayer element layer element, preferably the monolayer element, as the layer element (LE) is produced by cast film extrusion.

The invention further provides a process for producing an article of the invention, preferably for producing an assembly as defined above, below or in claims, by lamination comprising:

(i) an assembling step to arrange the layer element (LE) of the invention, preferably to form an assembly with at least one further layer element;

(ii) a heating step to heat up the formed assembly optionally, and preferably, in a chamber at evacuating conditions;

(iii) a pressing step to build and keep pressure on the assembly at the heated conditions for the lamination of the assembly to occur; and

(iv) a recovering step to cool and remove the obtained article comprising the laminated assembly.

The following process conditions of the lamination process are preferable for producing the photovoltaic (PV) module of the invention, and can be combined in any order.

The preferred process for producing the PV module of the invention is a lamination process, wherein the different functional layer elements, typically premade layer elements, of the PV module are laminated to form the integrated final PV module. The invention thus also provides a preferable lamination process for producing a photovoltaic (PV) module comprising, in the given order, a protective front layer element, a front encapsulation layer element, a photovoltaic element, a rear encapsulation layer element and a protective back layer element, wherein at least, the front encapsulation layer element or the rear encapsulation layer element, preferably both the front encapsulation layer element and the rear encapsulation layer element, is/are the layer element (LE) of the invention comprising, preferably consisting of, the polymer composition which comprises
a polymer (P);
silane group(s) containing units (b); and
a hindered amine compound (HALS) comprising a unit of formula (A0); as defined above and in claims;

wherein the process comprises the steps of:

(i) assembling step to arrange the protective front layer element, the front encapsulation layer element, the photovoltaic element, the rear encapsulation layer element and the protective back layer element, in given order, to form of a photovoltaic module assembly;

(ii) heating step to heat up the photovoltaic module assembly optionally in a chamber at evacuating conditions;

(iii) pressing step to build and keep pressure on the photovoltaic module assembly at the heated conditions for the lamination of the assembly to occur; and

(iv) recovering step to cool and remove the obtained photovoltaic module for later use.

Here it is to be understood that part of the layer elements of the assembly can be integrated together (e.g. by prelamination or (co)extrusion) before subjecting to the lamination process of the article, preferably of the PV module.

The lamination process is carried out in a laminator equipment which can be e.g. any conventional laminator which is suitable for the multilaminate to be laminated. The choice of the laminator is within the skills of a skilled person. Typically the laminator comprises a chamber wherein the heating, optional, and preferable, evacuation, pressing and covering (including cooling) steps (ii)-(iv) take place.

In a preferable lamination process of the invention:
the pressing step (iii) is started when at least one of the front encapsulation or rear encapsulation layer element(s) reaches a temperature which is at least 3 to 10° C. higher than the melting temperature of the polymer (P), preferably of the polymer of ethylene (a), present in said layer element (LE), preferably in said layer element (LE) in said rear encapsulation layer element; and
the total duration of the pressing step (iii) is up to 15 minutes.

The duration of the heating step (ii) is preferably up to 10 minutes, preferably 3 to 7 minutes. The heating step (ii) can be and is typically done step-wise.

Pressing step (iii) is preferably started when the at least one layer element reaches a temperature which is 3 to 10° C. higher than the melting temperature of the polymer (P), preferably of the polymer (a) of the layer element (LE).

The pressing step (iii) is preferably started when the layer element (LE), preferably of the polymer of ethylene (a), of layer element (LE) reaches a temperature of at least of 85° C., suitably to 85 to 150, suitably to 85 to 148, suitably 85 to 140, preferably 90 to 130, preferably 90 to 120, preferably 90 to 115, preferably 90 to 110, preferably 90 to 108° C.

At the pressing step (iii), the duration of the pressure build up is preferably up to 5, preferably 0.5 to 3 minutes. The pressure built up to the desired level during pressing step can be done either in one step or can be done in multiple steps.

At the pressing step (iii), the duration of holding the pressure is preferably up to 10, preferably 3.0 to 10, minutes.

The total duration of the pressing step (iii) is preferably from 2 to 10 minutes.

The total duration of the heating step (ii) and pressing step (iii) is preferably up to 25, preferably from 2 to 20, minutes.

The pressure used in the pressing step (iii) is preferably up to 1000 mbar, preferably 500 to 900 mbar.

Determination Methods

Unless otherwise stated in the description or in the experimental part, the following methods were used for the property determinations of the polymer composition, polar polymer and/or any sample preparations thereof as specified in the text or experimental part.

Melt Flow Rate

The melt flow rate (MFR) is determined according to ISO 1133 and is indicated in g/10 min. The MFR is an indication of the flowability, and hence the processability, of the polymer. The higher the melt flow rate, the lower the viscosity of the polymer. The MFR is determined at 190° C. for polyethylene. MFR may be determined at different loadings such as 2.16 kg (MFR₂) or 5 kg (MFR₅).

Density

Low density polyethylene (LDPE): The density of the polymer was measured according to ISO 1183-2. The sample preparation was executed according to ISO 1872-2 Table 3 Q (compression moulding).

Comonomer Contents:

The Content (Wt % and Mol %) of Polar Comonomer Present in the Polymer and the Content (Wt % and Mol %) of Silane Group(s) Containing Units (Preferably Comonomer) Present in the Polymer Composition (Preferably in the Polymer):

Quantitative nuclear-magnetic resonance (NMR) spectroscopy was used to quantify the comonomer content of the polymer composition or polymer as given above or below in the context.

Quantitative ¹H NMR spectra recorded in the solution-state using a Bruker Advance III 400 NMR spectrometer operating at 400.15 MHz. All spectra were recorded using a standard broad-band inverse 5 mm probehead at 100° C. using nitrogen gas for all pneumatics. Approximately 200 mg of material was dissolved in 1,2-tetrachloroethane-d₂ (TCE-d₂) using ditertiarybutylhydroxytoluen (BHT) (CAS 128-37-0) as stabiliser. Standard single-pulse excitation was employed utilising a 30 degree pulse, a relaxation delay of 3 s and no sample rotation. A total of 16 transients were acquired per spectra using 2 dummy scans. A total of 32k data points were collected per FID with a dwell time of 60 μs, which corresponded to to a spectral window of approx. 20 ppm. The FID was then zero filled to 64k data points and an exponential window function applied with 0.3 Hz line-broadening. This setup was chosen primarily for the ability to resolve the quantitative signals resulting from methylacrylate and vinyltrimethylsiloxane copolymerisation when present in the same polymer.

Quantitative ¹H NMR spectra were processed, integrated and quantitative properties determined using custom spectral analysis automation programs. All chemical shifts were internally referenced to the residual protonated solvent signal at 5.95 ppm. When present characteristic signals resulting from the incorporation of vinylacytate (VA), methyl acrylate (MA), butyl acrylate (BA) and vinyltrimethylsiloxane (VTMS), in various comonomer sequences, were observed (Randell89). All comonomer contents calculated with respect to all other monomers present in the polymer.

The vinylacytate (VA) incorporation was quantified using the integral of the signal at 4.84 ppm assigned to the *VA sites, accounting for the number of reporting nuclei per comonomer and correcting for the overlap of the OH protons from BHT when present:

VA=(I_{*VA}−(I_{ArBHT})/2)/1

The methylacrylate (MA) incorporation was quantified using the integral of the signal at 3.65 ppm assigned to the 1MA sites, accounting for the number of reporting nuclei per comonomer:

MA=I_{1MA}/3

The butylacrylate (BA) incorporation was quantified using the integral of the signal at 4.08 ppm assigned to the 4BA sites, accounting for the number of reporting nuclei per comonomer:

BA=I_{4BA}/2

The vinyltrimethylsiloxane incorporation was quantified using the integral of the signal at 3.56 ppm assigned to the 1VTMS sites, accounting for the number of reporting nuclei per comonomer:

VTMS=I_{1VTMS}/9

Characteristic signals resulting from the additional use of BHT as stabiliser, were observed. The BHT content was quantified using the integral of the signal at 6.93 ppm assigned to the ArBHT sites, accounting for the number of reporting nuclei per molecule:

BHT=I_{ArBHT}/2

The ethylene comonomer content was quantified using the integral of the bulk aliphatic (bulk) signal between 0.00-3.00 ppm. This integral may include the 1VA (3) and αVA (2) sites from isolated vinylacetate incorporation, *MA and αMA sites from isolated methylacrylate incorporation, 1BA (3), 2BA (2), 3BA (2), *BA (1) and αBA (2) sites from isolated butylacrylate incorporation, the *VTMS and αVTMS sites from isolated vinylsilane incorporation and the aliphatic sites from BHT as well as the sites from polyethylene sequences. The total ethylene comonomer content was calculated based on the bulk integral and compensating for the observed comonomer sequences and BHT:

E=(¼)*[I_{bulk}−5*VA−3*MA−10*BA−3*VTMS−21*BHT]

It should be noted that half of the a signals in the bulk signal represent ethylene and not comonomer and that an insignificant error is introduced due to the inability to compensate for the two saturated chain ends (S) without associated branch sites. The total mole fractions of a given monomer (M) in the polymer was calculated as:

fM=M/(E+VA+MA+BA+VTMS)

The total comonomer incorporation of a given monomer (M) in mole percent was calculated from the mole fractions in the standard manner:

M[mol %]=100*fM

The total comonomer incorporation of a given monomer (M) in weight percent was calculated from the mole fractions and molecular weight of the monomer (MW) in the standard manner:

M[wt %]=100*(fM*MW)/((fVA*86.09)+(fMA*86.09)+(fBA*128.17)+(fVTMS*148.23)+((1−NA−fMA−fBA−fVTMS)*28.05))

randall89: J. Randall, Macromol. Sci., Rev. Macromol. Chem. Phys. 1989, C29, 201. If characteristic signals from other specific chemical species are observed the logic of quantification and/or compensation can be extended in a similar manor to that used for the specifically described chemical species. That is, identification of characteristic signals, quantification by integration of a specific signal or signals, scaling for the number of reported nuclei and compensation in the bulk integral and related calculations. Although this process is specific to the specific chemical species in question the approach is based on the basic principles of quantitative NMR spectroscopy of polymers and thus can be implemented by a person skilled in the art as needed.

Adhesion Test:

The adhesion test is performed on laminated strips, the encaplulant film and backsheet is peeled of in a tensile testing equipment while measuring the force required for this.

A laminate consisting of glass, 2 encapsulant films and backsheet is first laminated. Between the glass and the first encapsulat film a small sheet of Teflon is inserted at one of the ends, this will generate a small part of the encapsulants and backsheet that is not adhered to the glass. This part will be used as the anchoring point for the tensile testing device. All vacuum laminations were performed at 145° C., using 2 minutes of evacuation time and 6 minutes holding time with membrane down at a pressure of 800 mbar.

The laminate is then cut along the laminate to form a 13 mm wide strip, the cut goes through the backsheet and the encapsulant films all the way down to the glass surface.

The laminate is mounted in the tensile testing equipment and the clamp of the tensile testing device is attached to the end of the strip.

The pulling angle is 90° in relation to the laminate and the pulling speed is 50 mm/min.

The adhesion is the average force per 50 mm of peeling starting 25 mm into the strip and ending at 75 mm.

The average force over the 50 mm is divided by 1,3 as the width of the strip is 13 mm and presented as adhesion strength (N/cm).

Melting Temperature, Crystallization Temperature (T_{cr}), and Degree of Crystallinity

The melting temperature Tm of the used polymers was measured in accordance with ASTM D3418. Tm and Tcr were measured with Mettler TA820 differential scanning calorimetry (DSC) on 3+−0.5 mg samples. Both crystallization and melting curves were obtained during 10° C./min cooling and heating scans between −10 to 200° C. Melting and crystallization temperatures were taken as the peaks of endotherms and exotherms. The degree of crystallinity was calculated by comparison with heat of fusion of a perfectly crystalline polymer of the same polymer type, e.g. for polyethylene, 290 J/g.

Experimental Part

Preparation of Polymer Examples for all Test Examples (Copolymer of Ethylene with Methyl Acrylate Comonomer and with Vinyl Trimethoxysilane Comonomer)

Polymer was produced in a commercial high pressure tubular reactor at a pressure 2500-3000 bar and max temperature 250-300° C. using conventional peroxide initiatior. Ethylene monomer, methyl acrylate (MA) polar comonomer and vinyl trimethoxy silane (VTMS) comonomer (silane group(s) containing comonomer (b)) were added to the reactor system in a conventional manner. CTA was used to regulate MFR as well known for a skilled person. After having the information of the property balance desired for the inventive final polymer (a), the skilled person can control the process to obtain the inventive polymer (a).

The amount of the vinyl trimethoxy silane units, VTMS, (=silane group(s) containing units), the amount of MA and MFR₂ are given in the table 1.

TABLE 1
Properties of base polymer used in all examples
of the storage stability test and adhesion test

| Properties of the | Test polymer | | | | |
|---|---|---|---|---|---|
| polymer obtained | | Inv. | Inv. | Inv. | Inv. |
| from the reactor | Ex. 1 | Ex. 2 | Ex. 3 | Ex. 4 | Ex. 5 |
| MFR_{2.16}, g/10 min | 3.0 | 2.0 | 4.5 | 16 | 18 |
| acrylate | MA 8.6 (22) | MA 8.1 (21) | MA 8.6 (22) | MA 8.0 | MA 10.4 |
| content, mol % (wt %) | | | | | |
| Melt | 90 | 92 | 90 | 89 | 85 |
| Temperature, ° C. | | | | | |
| VTMS | 0.38 (1.7) | 0.41 (1.8) | 0.38 (1.7) | 0.23 | 0.45 |
| content, mol % (wt %) | | | | | |

In above table 1 MA denotes the content of Methyl Acrylate comonomer present in the polymer and, respectively, VTMS content denotes the content of vinyl trimethoxy silane comonomer present in the polymer. The polymer was used in the below tests.

Storage Stability

HALS may have an adverse effect on storage stability of a polymer composition expressed e.g. as the decrease in MFR as a function of storing time. The decrease in MFR means that the viscosity of the melt of the polymer composition increases. As result the change of MFR may have adverse effect in producing the desired end application. For instance in applications where a layer of the polymer composition containing HALS is integrated, e.g. laminated, to a substrate of different material, e.g. to a glass substrate, the adhesion of the polymer composition, which contains HALS, to said substrate may not be sufficient to meet the demands required for the end application.

Production of Films

Inv.HALS 1 and Comp.HALS 1-4 were added to base polymer at 1600 ppm concentration. Two roll mill was used to homogenise the compound. The compound was homogenised at 140° C. for 5 minutes. The compound was then extruded into a 0.45 mm thick film at 140° C. Films used for storage stability studies were put in aluminium package before put into oven for storage at 70° C.

Lamination of adhesion samples was done as described in adhesion test.

TABLE 2
characterisation of INV. HALS 1 and Comp. HALS 1-4

| HALS Additive | CAS number |
|---|---|
| INV. HALS 1 | 65447-77-0 |
| Comp. HALS 1 | 71878-19-8 |
| Comp. HALS 2 | 52829-07-9 |
| Comp. HALS 3 | 129757-67-1 |
| Comp. HALS 4 | 191680-81-6 |

As seen in FIG. 1 the type of additive used have a strong impact on the rate of drop in MFR. A low drop rate indicates a longer shelf life of the film.

TABLE 3
MFR values during storage at 70° C. in aluminium packages

| | Days in 70° C. storage until |
|---|---|
| HALS additive | MFR2.16 kg < 2 [g/10 min] |
| INV. HALS 1 | 70 |
| Comp. HALS 1 | 7 |
| Comp. HALS 2 | 7 |
| Comp. HALS 3 | 35 |
| Comp. HALS 4 | 21 |

Table 3 show the clearly show the impact of the shelf life of the film depending on the type of HALS used.

Adhesion to Glass after Damp Heat Ageing

TABLE 4
Strip force, average value of three laminates, measured after exposure
to damp heat (DH) conditions (85° C., 85% relative humidity)

| | Initial | Strip force | Strip force | Strip force |
|---|---|---|---|---|
| Type of HALS | strip force | 500 h DH | 1000 h DH | 1500 h DH |
| additive | [N/cm] | [N/cm] | [N/cm] | [N/cm] |
| Comp. HALS 1 | 49 | 38 | 24 | 7 |
| Comp. HALS 2 | 117 | 18 | 7 | 5 |
| Inv. HALS 1 | 180 | 146 | 130 | 180 |
| Comp. HALS 3 | 180 | 141 | 39 | 19 |
| Comp. HALS 4 | 180 | 180 | 103 | 44 |

1-18. (canceled)

19. A layer element (LE) comprising one or more layer(s), wherein at least one layer comprises a polymer composition comprising
a polymer (P);
silane group(s) containing units (b); and
a hindered amine compound (HALS) comprising a unit of formula (A0): 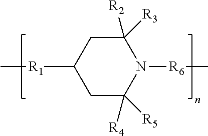
wherein
R₁ is a substituted or unsubstituted (C1-C20)hydrocarbylene group optionally interrupted with one or more heteroatom(s) selected from —O—, —N═ or —NR—; or a heteroatom selected from —O—, —N═ or —NR—;
R₂, R₃, R₄ and R₅ are each independently selected from a substituted or unsubstituted (C1-C20)hydrocarbyl group optionally interrupted with one or more heteroatom(s) selected from —O—, —N═ or —NR—;
R₆ is selected from substituted or unsubstituted (C1-C20)hydrocarbylene group optionally interrupted with one or more heteroatom(s) selected from —O—, —N═ or —NR—; provided that R₆ is attached to the ring atom of unit of formula (A0) via atom other than oxygen, —O—;
wherein the number of optional substituent(s) of each of R₁ to R₆ is independently selected from 1, 2 or 3; and the optional substituent(s) of each R₁ to R₆ are independently selected (C1-C20)hydrocarbyl group which can optionally be interrupted with one or more heteroatom(s) selected from —O—, —N═ or —NR— and which can optionally be substituted with (C1-C20)hydrocarbyl group optionally interrupted with one or more heteroatom(s) selected from —O—, —N═ or —NR—; or ═O group; or —N(R)₂;
R is independently selected from H or linear (C1-C8)alkyl group; and
n is 1 to 20.

20. The layer element according to claim 19, wherein the polymer (P) is a polyethylene polymer.

21. The layer element according to claim 19, wherein the hindered amine compound (HALS) of formula (A) is a compound of formula (A1), wherein:
R₁ is selected from a substituted or unsubstituted, saturated or unsaturated, straight or branched chain (C1-C20)alkylene group optionally interrupted with 1, 2, or 3 heteroatom(s) selected from —O—, —N═ or —NR—; a substituted or unsubstituted, unsaturated or partially saturated cyclic (C5-C8)alkylene group optionally having 1, 2 or 3 ring heteroatoms selected from —O—, —N═ or —NR—; a substituted or unsubstituted cyclic (C5-C8)arylene group optionally having 1, 2 or 3 ring heteroatoms selected from —O—, —N═ or —NR—; a substituted or unsubstituted (C1-C20)alkylene-cyclic (C5-C8)alkylene group which is optionally interrupted with —O—, —N═ or —NR—; a substituted or unsubstituted (C1-C20)alkylene-(C5-C8)arylene group which is optionally interrupted with —O—, —N═ or —NR—; a substituted or unsubstituted cyclic (C5-C8)alkylene-(C1-C20)alkylene group which is optionally interrupted with —O—, —N═ or —NR—; a substituted or unsubstituted (C5-C8)arylene-(C1-C20)alkylene group which is optionally interrupted with —O—, —N═ or —NR—; or a heteroatom selected from —O— or —NR—;
R₂, R₃, R₄ and R₅ are each independently selected from a substituted or unsubstituted, saturated or unsaturated, straight or branched chain (C1-C20)hydrocarbyl group optionally interrupted with 1, 2 or 3 heteroatom(s) selected from —O—, —N═ or —NR—;
R₆ is selected from a substituted or unsubstituted, saturated or unsaturated, straight or branched chain (C1-C20)alkylene group optionally interrupted with 1, 2, or 3 heteroatom(s) selected from —O—, —N═ or —NR—; a substituted or unsubstituted, unsaturated or partially saturated cyclic (C5-C8)alkylene group optionally having 1, 2 or 3 ring heteroatoms selected from —O—, —N═ or —NR—; a substituted or unsubstituted cyclic (C5-C8)arylene group optionally having 1, 2 or 3 ring heteroatoms selected from —O—, —N═ or —NR—; a substituted or unsubstituted (C1-C20)alkylene-cyclic (C5-C8)alkylene group which is optionally interrupted with —O—, —N═ or —NR—; a substituted or unsubstituted (C1-C20)alkylene-(C5-C8)arylene group which is optionally interrupted with —O—, —N═ or —NR—; a substituted or unsubstituted cyclic (C5-C8)alkylene-(C1-C20)alkylene group which is optionally interrupted with —O—, —N═ or —NR—; a substituted or unsubstituted (C5-C8)arylene-(C1-C20)alkylene group which is optionally interrupted with —O—, —N═ or —NR—; and
wherein the number of optional substituent(s) of each of R₁ to R₆ is independently selected from 1, 2 or 3; and the optional substituent(s) of each R₁ to R₆ are independently selected from saturated or unsaturated, straight or branched chain (C1-C20)hydrocarbyl group optionally interrupted with 1, 2 or 3 heteroatom(s) selected from —O—, —N═ or —NR—; a substituted or unsubstituted, unsaturated or partially saturated cyclic (C5-C8)hydrocarbyl group optionally having 1, 2 or 3 ring heteroatoms selected from —O—, —N═ or —NR—; a substituted or unsubstituted (C5-C8)aryl group optionally having 1, 2 or 3 ring heteroatoms selected from —O—, —N═ or —NR—; or ═O group; or —N(R)₂;
R is independently selected from H or linear (C1-C8)alkyl group; and
n is 2 to 20.

22. The layer element according to claim 19, wherein in the hindered amine compound (HALS) of formula (A) has pH of 9 or less.

23. The layer element according to claim 19, wherein the hindered amine compound (HALS) of formula (A) has a molecular weight of 300 to 6000.

24. The layer element according to claim 19, wherein the hindered amine compound (HALS) of formula (A) has Tm of 180° C. or less, preferably 15 to 150° C.

25. The layer element according to claim 19, wherein the polymer (P) is selected from a polymer of ethylene (a) which is selected from
(a1) a polymer of ethylene which bears silane group(s) containing comonomer;
(a2) a copolymer of ethylene with one or more polar comonomer(s) selected from (C1-C6)-alkyl acrylate or (C1-C6)-alkyl (C1-C6)-alkylacrylate comonomer(s), which copolymer (a2) bears silane group(s) containing units and which copolymer (a2) is different from the polymer of ethylene (a1); or
(a3) a copolymer of ethylene with one or more (C1-C10)-alpha-olefin comonomer which is different from polymer of ethylene (a1) and polymer of ethylene (a2).

26. The layer element according to claim 19, wherein the polymer of ethylene (a) is a (a2) copolymer of ethylene with one or more polar comonomer(s) selected from (C1-C6)-alkyl acrylate or (C1-C6)-alkyl (C1-C6)-alkylacrylate comonomer(s) and with silane group(s) containing comonomer.

27. The layer element according to claim 19, wherein the amount of the polar comonomer in the copolymer of ethylene (a2) is of 0.5 to 30.0 mol %.

28. The layer element according to claim 19, wherein the silane group(s) containing unit of polymer of ethylene (a) is a hydrolysable unsaturated silane compound represented by the formula (I):
R1SiR2qY3-q (I)
wherein
R1 is an ethylenically unsaturated hydrocarbyl, hydrocarbyloxy or (meth)acryloxy hydrocarbyl group,
each R2 is independently an aliphatic saturated hydrocarbyl group,
Y which may be the same or different, is a hydrolysable organic group; and
q is 0, 1 or 2;
the amount of the silane group(s) containing unit or, the silane group(s) containing comonomer, of polymer of ethylene (a) is of 0.01 to 2.0 mol %;
the polymer of ethylene (a) is produced by polymerisation in a high pressure polymerisation process using a radical initiator.

29. The layer element according to claim 19, wherein polymer of ethylene (a) has one or two, in any order,
a melt flow rate, MFR₂, of less than 20 g/10 min (according to ISO 1133 at 190° C. and at a load of 2.16 kg); or
a melting temperature, Tm, of 120° C. or less.

30. An article comprising the polymer composition according to claim 19.

31. The article according to claim 30, comprising the layer element (LE).

32. The article according to claim 31 which is an assembly comprising two or more layer elements, wherein at least one layer element is the layer element (LE).

33. The article according to claim 31, which is a photovoltaic (PV) module comprising a photovoltaic element and one or more further layer elements, wherein at least one layer element is the layer element (LE).

34. A photovoltaic (PV) module according to claim 33, comprising, in the given order, a protective front layer element, a front encapsulation layer element, a photovoltaic element, a rear encapsulation layer element and a protective back layer element, wherein the front encapsulation layer element and rear encapsulation layer element is the layer element (LE).

35. The photovoltaic (PV) module according to claim 33, wherein the protective front layer element, preferably the protective layer element and the protective back layer element are rigid layer element(s).

36. A process for producing an article, preferably a photovoltaic (PV) module, comprising two or more layer elements, wherein at least one layer element is the layer element (LE) according to claim 19, comprising the steps of:
assembling the layer element (LE) and one or more further layer elements to an assembly;
laminating the layer elements of the assembly in elevated temperature to adhere the elements together; and
recovering the obtained article.
